(19) United States
(12) Patent Application Publication
(10) Pub. No.: US 2021/0036195 A1
(43) Pub. Date: Feb. 4, 2021

(54) LED DEVICE FOR PROVIDING AREA LIGHT SOURCE AND MANUFACTURING METHOD THEREOF

(71) Applicant: LEDA-creative Inc., Taoyuan City (TW)

(72) Inventors: CHE-HSUAN HUANG, Taoyuan City (TW); SHU-HSIU CHANG, Taoyuan City (TW); HAO-CHUNG CHAN, New Taipei City (TW); Shao-Chun Chueh, Taoyuan City (TW)

(21) Appl. No.: 16/808,617

(22) Filed: Mar. 4, 2020

(30) Foreign Application Priority Data
Aug. 2, 2019 (TW) 108127494

(51) Int. Cl. H01L 33/58; H01L 33/62; H01L 25/075

(52) U.S. Cl. CPC H01L 33/58; H01L 33/62; H01L 2933/0066; H01L 2933/0058; H01L 25/0753

(57) ABSTRACT

An LED device for providing an area light source and a manufacturing method thereof are disclosed. The LED device for providing the area light source includes a substrate, a metal wiring layer and a plurality of LED chips. The coefficient of thermal expansion of the substrate ranges between 5 and 18 ppm/° C. on the X-Y direction, and a flexural strength σ ranges between 400 and 600 Mpa according to the ISO 178 test. The metal wiring layer is arranged on a top surface of the substrate. The plurality of LED chips are arranged on the top surface of the substrate for providing the area light source, and a cathode of the LED chips and an anode of the LED chips are separately and electrically connected to the metal wiring layer.

### CROSS-REFERENCE TO RELATED PATENT APPLICATION

This application claims the benefit of priority to Taiwan Patent Application No. 108127494, filed on Aug. 2, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an LED device and a manufacturing method thereof, and more particularly to the LED device for providing an area light source and a manufacturing method thereof.

### BACKGROUND OF THE DISCLOSURE

Considering that a light emitting diode (LED) generates a large amount of heat during operation, and the heat accumulated thereby decreases the brightness of LED, shifts the wavelength, reduces a lifetime of LED, and even directly damages the LED. Therefore, a good heat dissipation scheme has been one of the key technologies for LED related industries.

With the development of LED related technology, an application of LEDs have become wider and more diversified. For better adapting to the requirements of various application scenarios, a specification of LED has been developing toward being high powered and compact. In scenarios where a plurality of LEDs are used to provide the area light source, the heat that is generated by the LED increases as the amount of LEDs are increased; furthermore, the shorter the distance between LEDs, the more difficult it is for an accumulated heat to be dissipated. Therefore, the heat dissipation issue becomes even more difficult to resolve. In addition to the adverse effects on the LED, the heat has an effect on a substrate bearing the LED. During the operation of LED for providing the area light source, the heat that is accumulated in the substrate lead to thermal expansion of the substrate, hence, in addition to causing a warpage of the substrate, the accumulated heat affects an interval distance between LEDs. In a particular application scenario requiring higher precision in optical performance, the above-referenced inadequacies cannot be neglected.

Under the circumstances, in respect to the substrate for mounting the LED, how a heat dissipation performance of the entire product can be improved, and how the effects of thermal stress on the LED device can be reduced, have become important issues in the related art.

### SUMMARY OF THE DISCLOSURE

In response to the above-referenced technical inadequacies, the present disclosure provides an LED device for providing an area light source and a manufacturing method thereof to reduce the effects of thermal stress on the LED device and improving the thermal dissipation performance of a product.

For resolving the above-referenced technical inadequacies, in one aspect, the present disclosure provides an LED device for providing the area light source including the substrate, a metal wiring layer and a plurality of LED chips. A coefficient of thermal expansion (CTE) of the substrate ranges between 5 and 18 ppm/° C. on the X-Y direction, and a flexural strength σ ranges between 400 and 600 Mpa according to the ISO 178 test. The metal wiring layer is arranged on a top surface of the substrate. The plurality of LED chips is arranged on the top surface of the substrate for providing the area light source, and a cathode and an anode of an LED chip are separately electrically connected to the metal wiring layer.

In another aspect, the present disclosure provides a manufacturing method of LED device, including the following steps: providing the substrate having a CTE ranging between 13 and 18 ppm/° C. on the X-Y direction, and the flexural strength σ ranging between 400 and 600 Mpa according to the ISO 178 test; performing an image transfer etching on the top surface of the substrate to form the metal wiring layer; and arranging the plurality of LED chips on the top surface of the substrate, and the cathode of and the anode of the LED chip being separately electrically connected to the metal wiring layer, so as to provide the area light source by the plurality of LED chips.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic perspective view of an LED device according to a first embodiment of the present disclosure.

FIG. 2 is a schematic partial cross-sectional view of the LED device according to the first embodiment of the present disclosure, in which the arrangements of a single LED chip of the LED device and a substrate are shown.

FIG. 3 is a schematic partial bottom view of FIG. 2.

FIG. 4 is a schematic partial cross-sectional view showing another configuration of the LED device according to the first embodiment of the present disclosure.

FIG. 5 is a schematic partial cross-sectional view showing another configuration of the LED device according to the first embodiment of the present disclosure.

FIG. 6 is a schematic partial cross-sectional view showing another configuration of the LED device according to the first embodiment of the present disclosure.

FIG. 7 is a schematic partial cross-sectional view of the LED device according to the first embodiment of the present disclosure, in which the arrangements of a plurality of LED chips on the substrate are shown.

FIG. 8 is a schematic partial cross-sectional view of the LED device according to a second embodiment of the present disclosure, in which a bearing substrate and a plurality of excitation materials are further arranged on a top surface of the substrate.

FIG. 9 is a schematic partial cross-sectional view of the LED device according to a third embodiment of the present disclosure, in which a sensing element is further arranged on the top surface of the substrate.

FIG. 10 is a schematic partial cross-sectional view of the LED device according to a fourth embodiment of the present disclosure, in which the plurality of LED chips are packaged in a lens having a free curved structure.

FIG. 11 is a flow chart of the manufacturing method of the LED device according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

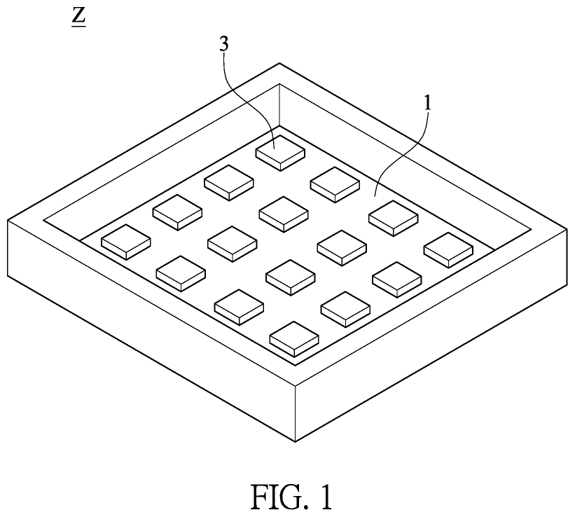

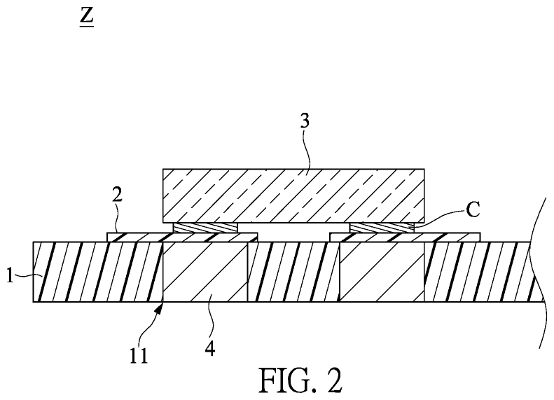

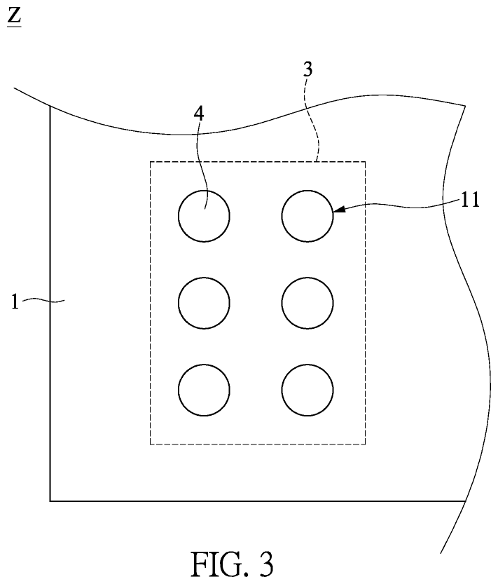

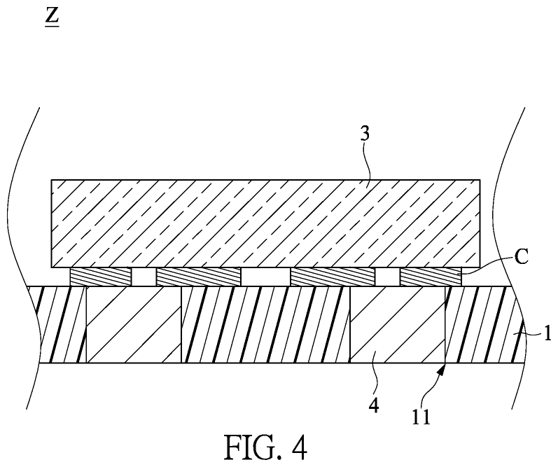

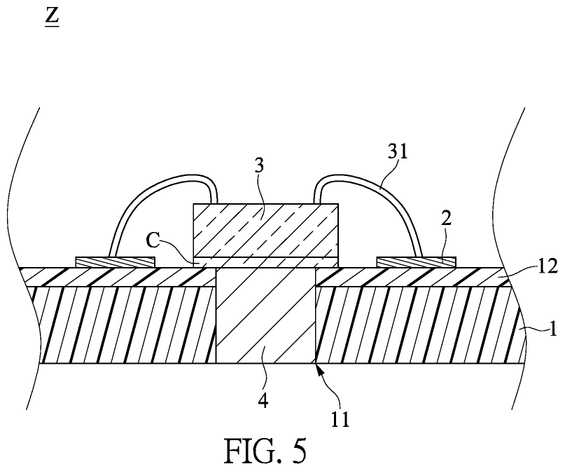

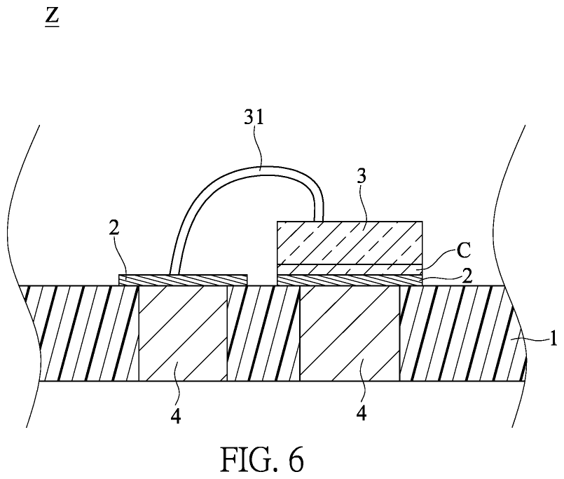

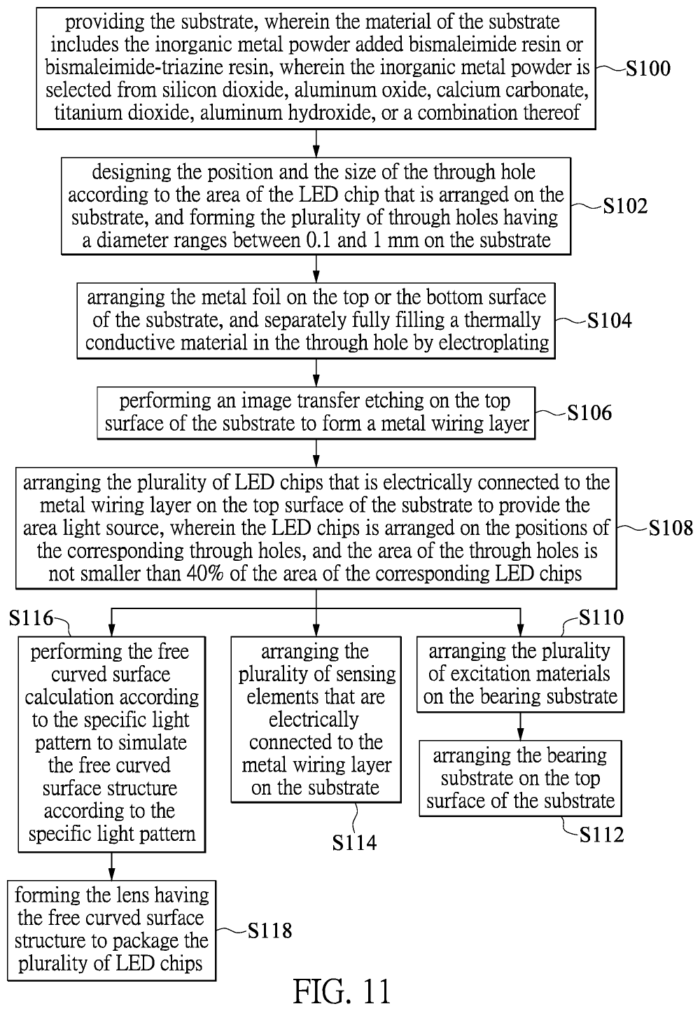

Referring to FIG. 1 to FIG. 7 and FIG. 11, FIG. 1 is the schematic perspective view of the LED device according to the first embodiment of the present disclosure. FIG. 2 is the schematic partial cross-sectional view of the LED device according to the first embodiment of the present disclosure, wherein the arrangements of one of the LED chips and the substrate are shown. FIG. 3 is the schematic partial upward view of FIG. 2. FIG. 4 is the schematic partial cross-sectional view showing another configuration of the LED device according to the first embodiment of the present disclosure. FIG. 5 is the schematic partial cross-sectional view showing another configuration of the LED device according to the first embodiment of the present disclosure. FIG. 6 is the schematic partial cross-sectional view showing another configuration of an LED device according to the first embodiment of the present disclosure. FIG. 11 is the flow chart of a manufacturing method of LED device according to the present disclosure. Referring to the above-mentioned drawings, the first embodiment of the present disclosure provides an LED device Z for providing the area light source, including a substrate 1, a metal wiring layer 2 and a plurality of LED chips 3.

Firstly, referring to FIG. 1 to FIG. 3 and FIG. 11, in one of the exemplary embodiments of the present disclosure, the plurality of LED chips 3 is arranged on a top surface of the substrate 1; and the cathode and the anode of LED chip 3 are separately electrically connected to the metal wiring layer 2 to receive electric power by the metal wiring layer 2. The area light source is provided by the plurality of LED chips 3 operating cooperatively. It should be noted that the quantity and the interval distance among LED chips 3 in FIG. 1 are simplified in the schematic drawing for illustrative purposes, and a wiring configuration is omitted in the drawings for simplification. A person having ordinary skill in the art can appropriately adjust the quantity, the arrangement and the wiring configuration etc. for practical requirements according to the spirit of the present disclosure.

It is widely known that a large amount of heat is generated during the operation of the LED chip 3; in addition to affecting the performance and the lifetime of the LED chip 3, the accumulated heat has an effect on the substrate 1. Specifically, in the scenario of employing the LED chip 3 having a side length shorter than 100 μm, the issue of heat accumulation may be more significant. To prevent the thermal expansion of the substrate 1 and the resulting issues (e.g., the warpage of the substrate 1, the change in the interval distance among LED chips 3) affecting the optical performance, the substrate 1 made by a material having a CTE ranging between 5 and 18 ppm/° C. on an X-Y direction is specifically employed, preferably, the substrate 1 having the CTE less than 15 ppm/° C. on the X-Y direction is employed in the present disclosure. In addition, in an exemplary embodiment of the present disclosure, the substrate 1 of the present disclosure also has a material property of a flexural strength σ ranging between 400 and 600 Mpa according to the ISO 178 test.

According to the experiment results, a plate material made by a bismaleimide (BMI) resin or a bismaleimide-triazine (BT) resin can be employed for the substrate 1 of the present disclosure. In addition, an inorganic metal powder being selected from silicon dioxide (SiO2), aluminum oxide (Al2O3), calcium carbonate (CaCO3), titanium dioxide (TiO2), aluminum hydroxide (Al(OH)3), or a combination thereof can be added in the BMI resin or the BT resin to adjust the CTE of the substrate 1 to range between 5 and 18 ppm/° C. Generally, the CTE of epoxy resin is approximately 30-50 ppm/° C. and the CTE of SiO2 is approximately 0.5-9 ppm/° C. In the present disclosure, the above-mentioned inorganic metal power is added into the BMI resin or the BT resin to reduce the CTE of the substrate 1 in order to attain a material property that meet the requirements of the present disclosure.

Referring to FIG. 1 to FIG. 3 and FIG. 11, after an appropriate material is chosen for the substrate 1 of the present disclosure, according to practical requirements, the position for arranging the LED chip 3 is designed. For example, when the LED device of the present disclosure is employed for illumination, the position for arranging the LED chip 3 can be designed according to a light pattern projected by the area light source of the present disclosure; or, when the LED device of the present disclosure is employed in an optical detector, the arrangement of the LED chip 3 and other elements should be considered at the same time. After the position for arranging the LED chip 3 is designed, according to the arrangement of the LED chip 3, the metal wiring layer 2 is arranged on the top surface of the substrate 1, and the cathode and the anode of the LED chip 3 are separately electrically connected to the metal wiring layer 2. Specifically, the metal wiring layer 2 can be formed on the top surface of the substrate 1 by image transfer etching, but the present disclosure is not limited thereto. The present disclosure, based on an appropriate choice of the material of the substrate 1, can effectively reduce the effect of thermal stress on the LED device Z; therefore, when the area light source is provided by the LED device Z of the present disclosure, the area light source can provide a high quality and stable optical output.

Further referring to FIG. 1 to FIG. 3 and FIG. 11, heat that is generated during the operation of the LED chips 3 affect the substrate 1; in addition, the accumulated heat also have an effect on the performance and the lifetime of the LED chip 3. Specifically, the previously described effects are more significant when a large number of LED chips 3 are closely arranged as the area light source. Therefore, in addition to choosing the material that is not easily affected by the accumulated heat for the substrate 1, the heat dissipation performance of the LED device Z should also be improved to protect the LED chip 3.

In practical applications, the present disclosure the manufacturing method of LED device can form a plurality of through holes 11 on the substrate 1, and a thermally conductive material 4 is filled into the plurality of through holes 11. Specifically, for filling a sufficient amount of the thermally conductive material 4 in the through hole 11 having larger diameter, the present disclosure arranges a metal foil on the top or the bottom surface of the substrate 1, and places the substrate 1 including the metal foil into an electroplating bath including a cathode spray box. After setting up the parameters of pulse electroplating by a rectifier, a periodic pulse reverse power supply is employed to control the electroplating by forwarding, pausing and reversing the current. A bridge structure can be formed near the center in the through hole 11 by interconnecting the plating layers of the thermally conductive material 4 on an inner wall of the through hole 11; furthermore, the thermally conductive material 4 is further plated to fully fill the through hole 11 to prevent the void formation issue that occurs in the regular direct current electroplating process due to high current density being locally concentrated on both sides of the substrate.

In an exemplary embodiment of the present disclosure, the thermal resistance (Rth) of substrate 1 including the plurality of through holes 11 and the plurality of thermally conductive materials 4 is less than 50 K/W. Specifically, after the appropriate LED chip 3 is chosen and the position for arranging the LED chip 3 is designed according to practical requirements, a position and a size of the through hole 11 are designed according to the position and the area of the LED chip 3 on the substrate 1. It should be noted that under the condition that the side length of the employed LED chip 3 is shorter than 100 μm, in an exemplary embodiment of the present disclosure, the plurality of through holes 11 having a diameter ranging between 0.1 and 1 mm is formed on the substrate 1 (according to the size of the corresponding LED chip 3, and the area of the through hole 11 is preferably not smaller than 40% of the area of the corresponding LED chip 3). In addition, the thermally conductive material 4 is separately filled in the plurality of through holes 11. After the metal wiring layer 2 is formed on the top surface of the substrate 1, the plurality of LED chips 3 is separately arranged on the positions of the corresponding through holes 11.

Referring to FIG. 2 and FIG. 3, in the present embodiment, six through holes 11 are formed on the substrate 1, and the thermally conductive material 4 is filled in each of the through holes 11. The plurality of metal wiring layers 2 on the top surface of the substrate 1 is separately covered on different thermally conductive materials 4, and the LED chip 3 is connected to the metal wiring layer 2 by a bonding material C, and subsequently, the cathode and the anode of the LED chip 3 are separately electrically connected to the metal wiring layer 2. The heat that is generated during the operation of the LED chip 3 can be transferred to the thermally conductive material 4 in the through hole 11, and then dissipated from the bottom surface of the substrate 1 via the thermally conductive material 4. It should be noted that the previously described “the area of the through holes 11 is not smaller than 40% of the area of the corresponding LED chips 3” should be interpreted as “the total area of the through holes 11 corresponding to the same one of the LED chips 3 is larger than 40% of the area of the said LED chip 3”. It should be noted that the arrangement of the LED chips 3 and the through holes 11 in the present disclosure is not limited to the embodiment that is shown in FIG. 2, “the plurality of LED chips 3 is separately arranged on the positions of the corresponding through holes 11” does not indicate that the positions of the geometrical centers of the plurality of through holes 11 must be directly corresponding to the geometrical centers of the LED chips 3. On the other hand, if the design of the through hole 11 can meet the requirements of the thermal dissipation of the LED chip 3, and the overlapping area between the through hole 11 and the LED chip 3 is not smaller than the area of the corresponding LED chip 3, the through hole 11 and the LED chip 3 should be considered as having corresponding relationship in the present disclosure.

Referring to FIG. 4 to FIG. 6, the corresponding relationship between the LED chip 3 and the through hole 11 in various examples of the first exemplary embodiment of the present disclosure is shown. First, referring to FIG. 4, in the present example, the plurality of through holes 11 is formed on the substrate 1, the thermally conductive materials 4 is separately filled in each of the through holes 11, and the LED chip 3 is connected to the thermally conductive material 4 by the bonding material C to allow the heat that is generated by the LED chip 3 to be dissipated via the thermally conductive material 4. Every bonding material C that connects to the cathode of the LED chip 3 can be conducted to one another via the thermally conductive material 4 in the through hole 11. Similarly, every bonding material C that is connecting to the anode of the LED chip 3 can also be conducted to one another via the thermally conductive material 4 in the through hole 11. In the present example, the functions of the thermally conductive material 4 are conducting the electric circuit of every LED chip 3 and transferring the heat that is generated by the LED chip 3.

Referring to FIG. 5, in the present example, the plurality of through holes 11 is formed on the substrate 1, the thermally conductive material 4 is separately filled in each of the through holes 11, each of the LED chips 3 is separately corresponding to different through holes 11, and the LED chip 3 is connected to the thermally conductive material 4 by the bonding material C to allow the heat that is generated by the LED chip 3 to be dissipated via the thermally conductive materials 4. In the present example, the area of every through hole 11 is not smaller than 40% of the area of the corresponding LED chip 3. In the present example, the top surface of the substrate 1 is covered with an insulation layer 12, and the metal wiring layer 2 is arranged on the insulation layer 12. The insulation layer 12 on the top surface of the substrate 1 is employed to insulate the thermally conductive material 4 in the through hole 11 and the metal wiring layer 2. In the present example of the first embodiment of the present disclosure, the cathode and the anode of the LED chip 3 are separately electrically connected to the metal wiring layer 2 by two wires 31. Therefore, in the present example, a function of the thermally conductive material 4 is simply transferring the heat that is generated by the LED chip 3, not being a part of the electric conducting path.

Furthermore, referring to FIG. 6, in the present embodiment, the metal wiring layers 2 on the top surface of the substrate 1 are separated from each other, and the metal wiring layers 2 separately cover the different thermally conductive materials 4. The LED chip 3 is connected to the metal wiring layer 2 on one of the thermally conductive materials 4, and the LED chip 3 is electrically connected to the metal wiring layer 2 on another thermally conductive material 4 by the wire 31. In the present example, the area of each one of the through holes 11 is not smaller than 40% of the area of the corresponding LED chip 3.

Referring to the above-mentioned various examples, a person having ordinary skill in the field of the present disclosure can understand the corresponding relationship between the LED chip 3 and the through hole 11, and can understand the preferred corresponding relationship between the LED chip 3 and the size of the through hole 11. Through the selection of the appropriate material for the substrate 1 and appropriately designing the through hole 11, the Rth of the substrate 1 including the plurality of through holes 11 and the plurality of thermally conductive materials 4 can be attained to be less than 50 K/W in the present disclosure, and therefore is beneficial for improving the heat dissipation performance of the entire product.

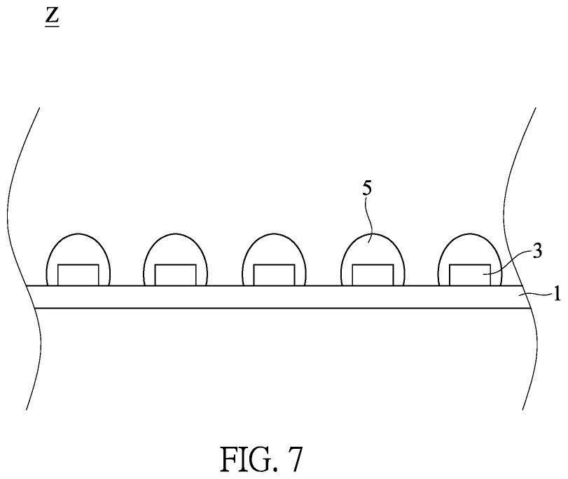

Referring to FIG. 7, in the first embodiment of the present disclosure, the plurality of LED chips 3 being arranged on the substrate 1 is separately covered by a plurality of primary optical lenses that is formed by a plurality of packaging adhesives 5. A light beam that is emitted by the LED chip 3 is refracted by the primary optical lens to provide the area light source required by a wide range projection of light. In addition, by virtue of the special design of the substrate 1 in the present disclosure, the LED device Z of the present disclosure can provide a stable and high quality area light source for illumination.

Overall, in a first exemplary embodiment of the present disclosure, the manufacturing method of the LED device Z comprises the following steps:

S100: providing the substrate 1, wherein the material includes the inorganic metal powder added BMI resin or BT resin, and wherein the inorganic metal powder is selected from SiO₂, Al₂O₃, CaCO₃, TiO₂, Al(OH)₃ or a combination thereof;

S102: designing the position and the size of the through hole 11 according to the area of the LED chip 3 that is then arranged on the substrate 1, and forming the plurality of through holes 11 having a diameter ranging between 0.1 and 1 mm on the substrate 1;

S104: arranging the metal foil on the top surface or the bottom surface of the substrate 1, and employing electroplating to separately fill the thermally conductive material 4 into the through hole 11;

S106: performing the image transfer etching to form the metal wiring layer 2 on the top surface of the substrate 1; and

S108: arranging the plurality of LED chips 3 that are electrically connected to the metal wiring layer 2 on the top surface of the substrate 1 to provide the area light source; the LED chip 3 being arranged on the position of the corresponding through hole 11; and the area of the through holes 11 being not smaller than 40% of the area of the corresponding LED chip 3.

### Second Embodiment

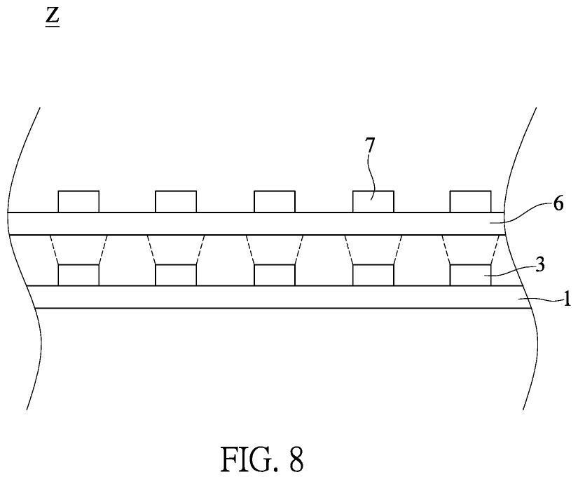

Referring to FIG. 8 and FIG. 11, FIG. 8 is the schematic partial cross-sectional view of an LED device according to a second embodiment of the present disclosure, wherein a bearing substrate σ and a plurality of excitation materials 7 are further arranged on the top surface of the substrate 1. In contrast to the LED device Z of the first embodiment providing the illumination directly from the light beam that is emitted by the LED chip 3, the LED device Z of the present embodiment provides a first light beam having a first wavelength that is emitted by the LED chip 3, and the first light beam is converted to a second light beam having a second wavelength after the first light beam is projected on the excitation material 7. In other words, the first light beam having the first wavelength emitted by the LED chip 3 is converted to the second light beam having the second wavelength by the excitation material 7. Therefore, the LED device Z of the present embodiment provides the light beam having the second wavelength. It should be noted that the wavelength of the light beam provided by the LED device Z is not limited in the present disclosure, the present embodiment simply emphasizes the light beam emitted by the LED chip 3 undergoing a conversion, rather than emphasizing that all LED chips 3 in the LED device Z should have the same initial wavelength. In addition, based on the chosen excitation material 7, the wavelengths of the light beams emitted by the LED chips 3 can be separately converted to different wavelengths; furthermore, blending the light beams having different wavelengths can provide various illumination results of different wavelengths.

In other words, in a second exemplary embodiment of the present disclosure, the manufacturing method of the LED device Z, except the steps S100-S108 that are described in the first embodiment, further comprises the following steps:

S110: arranging the plurality of excitation materials 7 on the bearing substrate 6; and

S112: arranging the bearing substrate 6 on the top surface of the substrate 1.

Therefore, the light beam emitted by the LED chip 3 can be converted by the excitation material 7 to the light beam having the second wavelength, and then project outward from the LED device Z.

### Third Embodiment

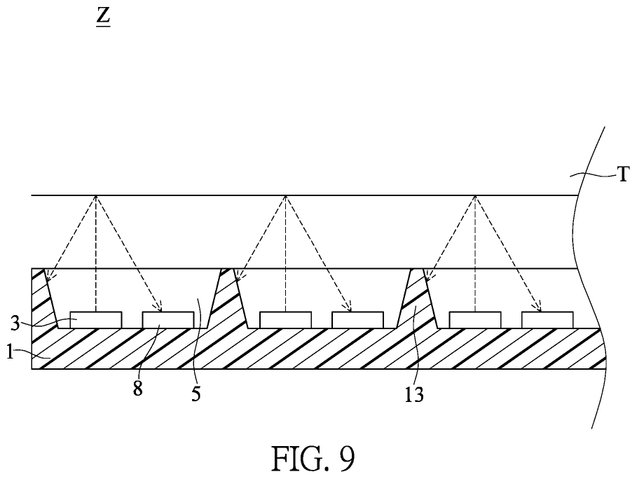

Referring to FIG. 9 and FIG. 11, FIG. 9 is the schematic partial cross-sectional view of the LED device according to a third embodiment of the present disclosure, wherein a sensing element 8 is further arranged on the top surface of the substrate 1. In a particular field of optical detection application (e.g., wearable heart rate measuring device), essentially, the sensing element 8 directly receives a light beam having a particular wavelength that is emitted by a luminous element or a light beam having another wavelength from the reflection from an object. The sensing element 8 then generates a detection signal according to the received results.

In the present embodiment, in addition to the plurality of LED chips 3 being arranged on the substrate 1 of the LED device Z, a plurality of sensing elements 8 is arranged on the substrate 1 of the LED device Z. The plurality of sensing elements 8 is electrically connected to the metal wiring layer 2 (not shown in the drawings). Furthermore, for precisely distinguishing the light beams that are emitted from each of the LED chips 3, in the present embodiment, a plurality of dividers 13 is disposed on the substrate 1. Each pair of the LED chip 3 and the sensing element 8 is arranged into different spaces that are divided by the plurality of dividers 13. When the LED device Z of the present disclosure is employed in a wearable device, the light beams that are emitted by the LED chip 3 first project on a biological tissue T (e.g., the skin surface, or the tissues, such as blood vessels that are under the skin), and then are reflected by the biological tissue T. In the present embodiment, part of the light beams being reflected by the biological tissue T is received by the sensing element 8. A light signal being received by the sensing element 8 can be converted to an electrical signal by the sensing element 8, and the electrical signal is transferred to a central processing unit (not shown in the drawings) by the metal wiring layer 2 for processing.

In brief, in the third exemplary embodiment of the present disclosure, the manufacturing method of LED device Z, in addition to the steps S100-S108 that are described in the first embodiment, further comprises the following steps: S114: arranging the plurality of sensing elements 8 that are electrically connected to the metal wiring layer 2 on the substrate 1.

It should be noted that the substrate 1 that is chosen in the present disclosure has the properties of low CTE and good flexibility at the same time. Therefore, when the LED device Z of the present disclosure is employed in the previously described wearable device, the LED device Z of the present disclosure can appropriately complement the wearable device in the curve radian.

### Fourth Embodiment

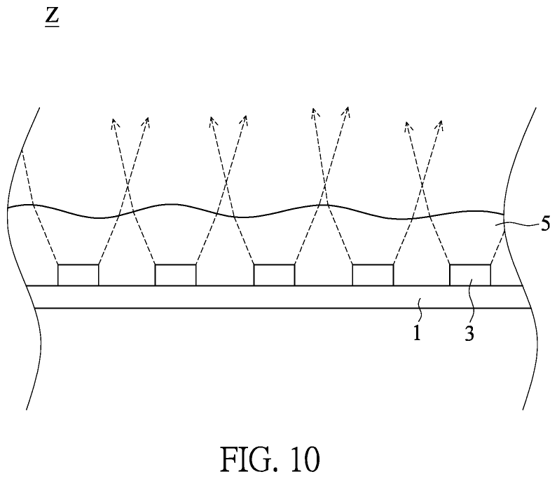

Referring to FIG. 10 and FIG. 11, FIG. 10 is the schematic partial cross-sectional view of the LED device according to a fourth embodiment of the present disclosure, wherein the plurality of LED chips are packaged in a lens having a free curved structure. In contrast to the LED device Z of the first embodiment, where the LED chips 3 are separately packaged in individual packaging adhesive 5, and according to practical requirements, a photo mask having a secondary optical structure can be further employed to adjust the path of the light beam, in the LED device Z of the present embodiment, a plurality of LED chips 3 are packaged in the primary optical structure that is formed by a free curved lens 8.

Specifically, when the LED device Z of the present disclosure is employed for projecting a specific light pattern, the designer of the LED device Z can use software to perform a free curved surface calculation in order to simulate a free curved surface for the LED device Z according to the specific light pattern (details on the technique of the simulation is not the focus of the present disclosure, and are omitted herein). The designer of the LED device Z can then arrange the LED chips 3 according to the simulation results, and utilize the packaging adhesive 5 to form the lens having the free curved surface structure to package the plurality of LED chips 3.

In other words, in the fourth embodiment of the present disclosure, the manufacturing method of the LED device Z, in addition to steps S100-S108 that are described in the first embodiment, further comprises the following steps:

S116: using the free curved surface calculation to simulate the free curved surface structure according to the specific light pattern; and

S118: forming the lens having the free curved surface structure to package the plurality of LED chips 3.

In conclusion, the manufacturing method of LED device Z is beneficial to the minimization and the precision of the device. By integrating the manufacturing method of the LED device Z and the properties of low CTE and high flexibility of the substrate 1 of the present disclosure, the application of the LED device Z of the present disclosure can be broadened; and can provide a stable optical output with higher quality. Specifically, the advantage of the present disclosure can be significantly highlighted when the LED device Z of the present disclosure is employed in a product including a small chip and a highly integrated circuit.

### Advantages of the Embodiments

An advantage of the present disclosure is that the LED device for providing the area light source and the manufacturing method thereof in the embodiments of the present disclosure can reduce the effect of thermal stress on the LED device and improve the heat dissipation performance of the entire product by the technical features of “the CTE ranging between 5 and 18 ppm/° C. on the X-Y direction” and “the flexural strength σ ranging between 400 and 600 Mpa according to the ISO 178 test.”

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An LED device for providing an area light source, comprising:
a substrate having a coefficient of thermal expansion ranging between 5 and 18 ppm/° C. on the X-Y direction, and a flexural strength σ ranging between 400 and 600 Mpa according to the ISO 178 test;
a metal wiring layer being arranged on a top surface of the substrate; and
a plurality of LED chips being arranged on a top surface of the substrate for providing the area light source, a cathode of the LED chips and an anode of the LED chips being separately and electrically connected to the metal wiring layer.

2. The LED device according to claim 1, wherein a plurality of through holes are formed on the substrate, and a plurality of thermally conductive materials are separately filled in the plurality of through holes; the plurality of LED chips are arranged on positions respectively corresponding to the through holes, wherein a diameter of the through holes ranges between 0.1 and 1 mm, and the thermal conductivity of the substrate having the plurality of through holes and the plurality of thermally conductive materials is under 50 K/W.

3. The LED device according to claim 2, wherein a side length of the LED is shorter than 100 μm, and an area of the through holes is not smaller than 40% of an area of the corresponding LED chips.

4. The LED device according to claim 1, wherein a material of the substrate includes an inorganic metal powder added bismaleimide resin or an inorganic metal powder added bismaleimide-triazine resin, wherein the inorganic metal powder is selected from silicon dioxide, aluminum oxide, calcium carbonate, titanium dioxide, aluminum hydroxide, or a combination thereof.

5. The LED device according to claim 1, wherein a distance among the plurality of LED chips is shorter than 1 mm.

6. The LED device according to claim 1, wherein the LED device further comprises:
a bearing substrate being arranged on the top surface of the substrate; and
a plurality of excitation materials being arranged on the bearing substrate;
wherein a first light beam having a first wavelength emitted by the LED chips is converted to a second light beam having a second wavelength by the excitation material.

7. The LED device according to claim 1, wherein the LED device further comprises:
a plurality of sensing elements being arranged on the substrate and being electrically connected to the metal wiring layer;
wherein a light beam emitted by the LED chips is reflected by a biological tissue and then received by the sensing elements to be converted into an electrical signal.

8. The LED device according to claim 1, wherein the plurality of LED chips are packaged in a primary optical structure that is formed by a free curved lens.

9. A manufacturing method of an LED device, comprising the following steps:
providing a substrate having a coefficient of thermal expansion ranging between 13 and 18 ppm/° C. on the X-Y direction, and a flexural strength σ ranging between 400 and 600 Mpa according to the ISO 178 test;
performing an image transfer etching on a top surface of the substrate to form a metal wiring layer; and
arranging a plurality of LED chips on the top surface of the substrate, a cathode of the LED chips and an anode of the LED chips being separately and electrically connected to the metal wiring layer, and an area light source being provided by the plurality of LED chips.

10. The manufacturing method according to claim 9, wherein, before the step of the image transfer etching, the manufacturing method further comprises the following steps:
forming a plurality of through holes having a diameter ranging between 0.1 and 1 mm on the substrate;
arranging a metal foil on the top surface or a bottom surface; and
filling a thermally conductive material in the through holes by periodic pulse electroplating;
wherein, after the step of the image transfer etching, the plurality of LED chips are arranged on positions respectively corresponding to the through holes.

11. The manufacturing method according to claim 10, wherein a side length of the LED chips is shorter than 100 μm, and the manufacturing method further comprises the following steps: designing a position and a size of the through holes according to an area of the LED chips, such that an area of the through holes being formed on the substrate is not smaller than 40% of an area of the corresponding LED chips.

12. The manufacturing method according to claim 9, wherein a material of the substrate includes an inorganic metal powder added bismaleimide resin or an inorganic metal powder added bismaleimide-triazine resin, wherein the inorganic metal powder is selected from silicon dioxide, aluminum oxide, calcium carbonate, titanium dioxide, aluminum hydroxide, or a combination thereof.

13. The manufacturing method according to claim 9, wherein, in the step of arranging the LED chips, a distance among the plurality of LED chips is shorter than 1 mm.

14. The manufacturing method according to claim 9, wherein the manufacturing method further comprises the following steps:
arranging a plurality of excitation materials on a bearing substrate; and
arranging the bearing substrate on the top surface of the substrate;
wherein a first light beam having a first wavelength emitted by the LED chips is converted to a second light beam having a second wavelength by the excitation material.

15. The manufacturing method according to claim 9, wherein the manufacturing method further comprises the following steps:
arranging a plurality of sensing elements on the substrate, and the sensing elements being electrically connected to the metal wiring layer;
wherein, a light beam emitted by the LED chips is reflected by a biological tissue and then received by the sensing elements to be converted to an electrical signal.

16. The manufacturing method according to claim 9, wherein the manufacturing method further comprises the following steps:
using a free curved surface calculation to simulate a corresponding free curved structure according to a light pattern; and
forming a lens having the free curved structure to package the plurality of LED chips.
